(19) United States
(12) Patent Application Publication
(10) Pub. No.: US 2005/0141648 A1
(43) Pub. Date: Jun. 30, 2005

(54) Time signal peripheral

(75) Inventors: Ruan Lourens, Chandler, AZ (US); Douglas LeRoy Chaffee, Queen Creek, AZ (US)

Correspondence Address: BAKER BOTTS L.L.P.;PATENT DEPARTMENT, 98 SAN JACINTO BLVD., SUITE 1500, AUSTIN, TX, 78701-4039, US

(73) Assignee: MICROCHIP TECHNOLOGY INCORPORATED

(21) Appl. No.: 10/746,590

(22) Filed: Dec. 24, 2003

(51) Int. Cl. H04L 27/06; H03D 1/00

(52) U.S. Cl. 375/340

(57) ABSTRACT

A time signal peripheral may include a radio receiver, decoder/demodulator and time registers. The time signal peripheral may receive, detect and store time information from time signals, e.g., WWV, WWVH, WWVB (USA), JJY (Japan), MSF (UK) and the like. The time information may be used for a self setting clock, and the clock may be used as a reference in time sensitive applications, devices and systems. A digital processor may be coupled to and control the time signal peripheral. The digital processor may be used to decode the time information in the received time signal, store the decoded time information and make the time information available for use by a device and/or system, or the time signal peripheral may do these functions, allowing the digital processor to be used for higher level applications. The time signal peripheral may be fabricated on an integrated circuit die with or without the digital processor. The time signal peripheral and the digital process may be on a separate integrated circuit dice and be packaged together in a signal integrated circuit package.

### RELATED PATENT APPLICATIONS

This application is related to commonly owned U.S. patent application Ser. No. 10/670,619, filed Sep. 25, 2003, entitled “Q-Quenching Super-Regenerative Receiver,” by Ruan Lourens; and U.S. patent application Ser. No. ______, filed Dec. 15, 2003, entitled “A Time Signal Receiver and Decoder,” by Ruan Lourens, Layton W. Eagar and Russell Eugene Cooper, both hereby incorporated by reference herein for all purposes.

### FIELD OF THE INVENTION

The present invention relates generally to devices using radio time signals for accurately setting time, and more particularly to a time signal peripheral having a radio receiver and a digital processor.

### BACKGROUND OF THE INVENTION TECHNOLOGY

The Time and Frequency Division of the National Institute of Standards and Technology (NIST) broadcasts time information, traceable to an atomic time standard, that is used as a time measurement standard. Various radio frequencies are used to transmit this time standard. The NIST radio station WWVB transmits at a very low frequency (VLF) of 60 kHz and effectively distributes standard time information to better than one second throughout the North American continent. Other VLF sites transmitting time standards have reception coverage mainly in the far east—JJY (Japan) and Europe—MSF (UK).

The NIST radio stations (e.g., WWV, WWVH, WWVB) are continuously being used for both precise frequency and time calibration, The demand for precise frequency and time calibration is constantly growing as manufacturers continue to create new, lower cost products, in an effort to place “Atomic Time” in every home and office. However, acceptance of highly accurate and automatically set time appliances is greatly dependent upon cost and ease in implementation. Integrated circuit technologies have reduced the cost of time measurement, recording and display systems, e.g., digital clocks, parking meters, etc. However, complex and expensive receiving equipment is presently used to receive the time signals from the NIST radio stations.

Apparatus and systems requiring accurate time information may be for example, but not limited to, clocks, time of use utility meters, traffic lights; bus, train and plane scheduling apparatus; speed measuring instruments used in combination with global positioning satellite (GPS) devices, timers, parking meters, and the like.

Therefore, what is needed is a low cost time signal peripheral having a radio receiver and digital processor that can receive, decode and store the precise time from the NIST radio stations and the like, and make the precise time available as decoded time information.

### SUMMARY OF THE INVENTION

The invention overcomes the above-identified problems as well as other shortcomings and deficiencies of existing technologies by providing a time signal peripheral comprising a radio receiver and a digital processor for receiving, decoding and storing time information from time signals, e.g., WWV, WWVH, WWVB (USA), JJY (Japan), MSF (Europe) and the like. The digital processor, e.g., microcontroller, microprocessor, programmable logic array (PLA), application specific integrated circuit (ASIC), digital signal processor (DSP) and the like, may control the radio receiver and decode the time information from the received time signal. The radio receiver may be a super-regenerative receiver, a preferred embodiment of which is more fully described in commonly owned co-pending U.S. patent application Ser. No. 10/670,619, filed Sep. 25, 2003, entitled “Q-Quenching Super-Regenerative Receiver,” by Ruan Lourens. The radio receiver may be a direct conversion receiver, preferred embodiments of which are more fully described in commonly owned co-pending U.S. patent application Ser. No. ______, filed Dec. 15, 2003, entitled “A Time Signal Receiver and Decoder”, by Ruan Lourens, Layton W. Eagar and Russell Eugene Cooper, wherein the aforementioned patent applications are hereby incorporated by reference herein for all purposes.

In accordance with exemplary embodiments of the present invention, a time signal radio receiver provides demodulated time signal information to a digital processor which may decode the time information in the time signal and then store the decoded time information. The radio receiver provides a demodulated envelope of a received time signal to the digital processor. The digital processor decodes this demodulated signal to produce the time information. In addition, the digital processor may control the characteristics of the radio receiver to further improve reception performance thereof.

The time signal peripheral may be used to supply accurate time information to apparatus and systems requiring the determination of accurate time(s), e.g., clocks, time of use utility meters, traffic lights; bus, train and plane scheduling apparatus; speed measuring instruments used in combination with global positioning satellite (GPS) devices, timers, parking meters, and the like.

The present invention may be fabricated in one or more integrated circuit dice un-packaged on a leadframe or substrate, or encapsulated in a plastic, epoxy and/or ceramic integrated circuit package, e.g., PDIP, SOIC, MSOP, TSSOP, QSOP and the like.

A technical advantage of the present invention is using a physically small magnetic coil antenna resonant in the low frequency and medium frequency reception bands. Another technical advantage is fabricating the receiver in an integrated circuit. Still another technical advantage is adding input buffering stages so as to further reduce radiated noise from the receiver circuit. Another technical advantage is low power operation. Yet another technical advantage is efficient detection of digitally modulated data signals, e.g., WWVB. Yet another technical advantage is a low cost integrated circuit solution for apparatus and systems requiring precise time.

Features and advantages of the invention will be apparent from the following description of the embodiments, given for the purpose of disclosure and taken in conjunction with the accompanying drawing.

### BRIEF DESCRIPTION OF THE DRAWING

A more complete understanding of the present disclosure and advantages thereof may be acquired by referring to the following description taken in conjunction with the accompanying drawing, wherein:

FIG. 1 illustrates schematic block diagram of a time signal peripheral having a receiver demodulator/decoder and time register(s), according to an exemplary embodiment of the present invention;

FIG. 2 illustrates a schematic block diagram of a time signal peripheral having a radio receiver and a digital processor, according to the exemplary embodiment of the present invention;

FIG. 3 illustrates a schematic block diagram of a time signal receiver and signal demodulator in combination with digital decoders, according to another exemplary embodiment of the present invention; and

FIG. 4 illustrates the WWVB time code format.

While the present invention is susceptible to various modifications and alternative forms, specific exemplary embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Referring now to the drawings, the details of exemplary embodiments of the present invention are schematically illustrated. Like elements in the drawing will be represented by like numbers, and similar elements will be represented by like numbers with a different lower case letter suffix.

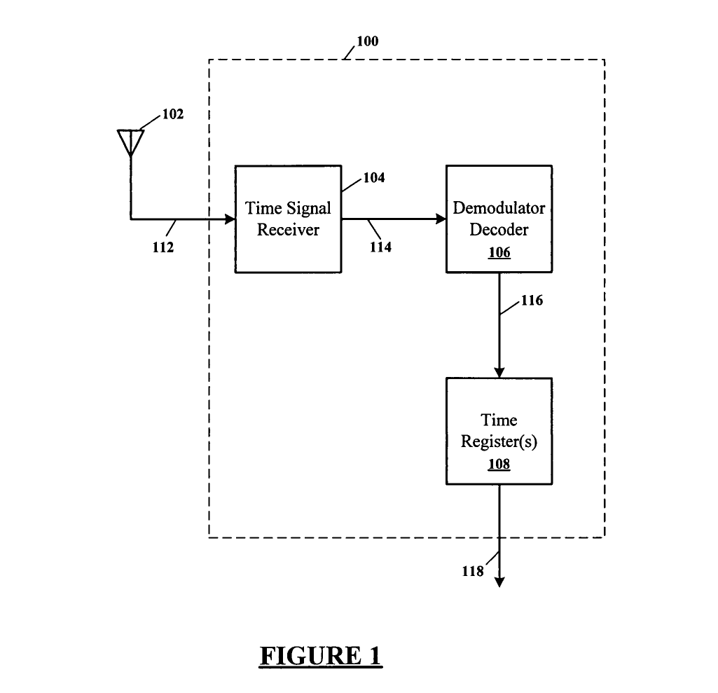

Referring to FIG. 1, depicted is a schematic block diagram of a time signal peripheral having a time signal radio receiver, demodulator/decoder, and a time register(s), according to an exemplary embodiment of the present invention. A time signal, e.g., WWV, WWVH, WWVB (USA); JJY (Japan), MSF (UK) and the like, may be received on antenna 102, the received time signal 112 is coupled to an input of a time signal receiver 104 which separates the time signal from other unwanted signals and amplifies the desired time signal sufficiently for demodulation and decoding thereof. An amplified time signal 114 is applied to a demodulator/decoder 106 which demodulates the time signal information from the time signal and decodes the time signal information into useful accurate time. The decoded time signal information 116 may be stored in a time register(s) 108 for use by external devices (not shown). Accurate time information is available on an output 118 of the time register(s) 108. The time signal peripheral of the present invention may be fabricated on an integrated circuit die or dice, generally represented by the numeral 100. The die or dice may be on leadframe, un-packaged or encapsulated in an integrated circuit package.

A more detailed example of a time signal receiver 104 and/or demodulator/decoder 106 may be a super-regenerative receiver, a preferred embodiment of which is more fully described in commonly owned co-pending U.S. patent application Ser. No. 10/670,619, filed Sep. 25, 2003, entitled “Q-Quenching Super-Regenerative Receiver,” by Ruan Lourens. The radio receiver also may be a direct conversion receiver, preferred embodiments of which are more fully described in commonly owned co-pending U.S. patent application Ser. No. ______, filed Dec. 15, 2003, entitled “A Time Signal Receiver and Decoder” by Ruan Lourens, Layton W. Eagar and Russell Eugene Cooper, wherein the aforementioned patent applications are hereby incorporated by reference herein for all purposes.

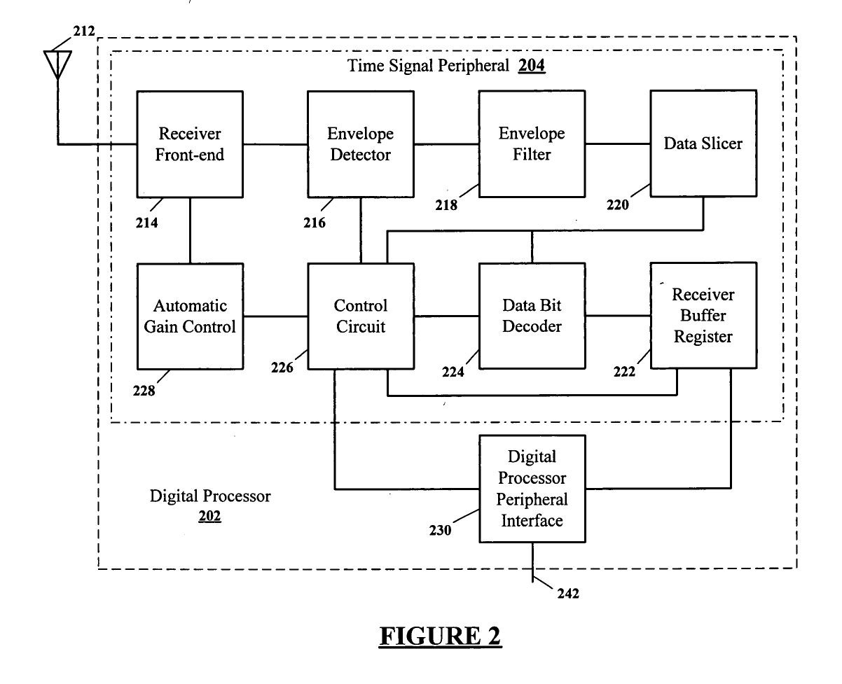

Referring to FIG. 2, depicted is a schematic block diagram of a time signal peripheral and digital processor, according to an exemplary embodiment of the present invention. A time signal peripheral 204 may comprise a receiver front-end 214 coupled to an antenna 212, a envelope detector 216 coupled to an output of the receiver front end 214, an envelope filter 218 coupled to a output of the envelope detector 216, a data slicer 220 coupled to an output of the envelope filter 218, a control circuit 226 and data bit decoder 224 coupled to an output of the data slicer 220, automatic gain control 228 coupled to an output of the control circuit 226, and a receiver buffer register 222 coupled to an output of the data bit decoder 224.

A digital processor 202 may be coupled to the time signal peripheral 204 with, for example but not limited to, a digital processor peripheral interface 230. The peripheral interface 230 may have an output 242 adapted to supply time information determined from the time signal received on the antenna 212.

The digital processor 202 may access the control circuit 226 through the peripheral interface 230, or may connect to the control circuit 226 directly. The control circuit 226 may control the automatic gain control 228 based upon signal levels at the envelope detector 216. The automatic gain control 228 may control the sensitivity of the receiver front-end to prevent signal overload thereof. The control circuit 226 may control the data bit decoder 224 and the receiver buffer register 222 based upon information from the data slicer 220. The control circuit 226 may control when time information is transferred from the receiver buffer register 222 to the peripheral interface 230.

In one exemplary embodiment of the invention, the time signal peripheral 204 may be fabricated on an integrated circuit die (not shown) and function independently from the digital processor 202. The digital processor may be an industry standard processor, e.g., microcontroller, microprocessor, programmable logic array (PLA), application specific integrated circuit (ASIC), digital signal processor (DSP) and the like.

In another exemplary embodiment of the invention, the digital processor 202 may perform the functions of the control circuit 226, thus eliminating the need for the control circuit 226. In a further exemplary embodiment of the invention the digital processor 202 and the time signal peripheral 204 may be fabricated on an integrated circuit die or dice and may be un-encapsulated on a leadframe or substrate, or may be encapsulated in an integrated circuit package, e.g., PDIP, SOIC, MSOP, TSSOP, QSOP and the like.

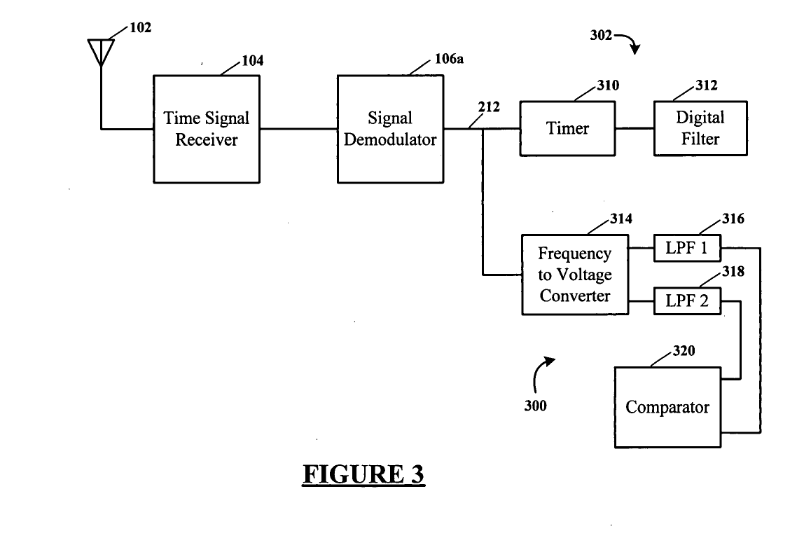

Referring to FIG. 3, depicted is a schematic block diagram of the time signal receiver 104 in combination with digital decoders, according to another exemplary embodiment of the present invention. A time signal is received on the antenna 102 and the desired time signal is amplified in the time signal receiver 104. The amplified time signal may be detected or demodulated with the signal demodulator 106a and the demodulated/detected time signal may be coupled to a mixed signal decoder 300 and/or a digital decoder 302. The mixed signal decoder 300 may comprise a frequency-to-voltage converter 314, a first low pass filter 316, a second low pass filter 3188, and a voltage comparator 3200. The digital decoder 302 may comprise a timer 3100 and a digital filter 312. The time signal receiver 104 may receive and the signal demodulator 106a may demodulate frequency modulated signal information and/or amplitude modulated signal information which may be processed by the mixed signal decoder 300 and/or the digital decoder 302, respectively.

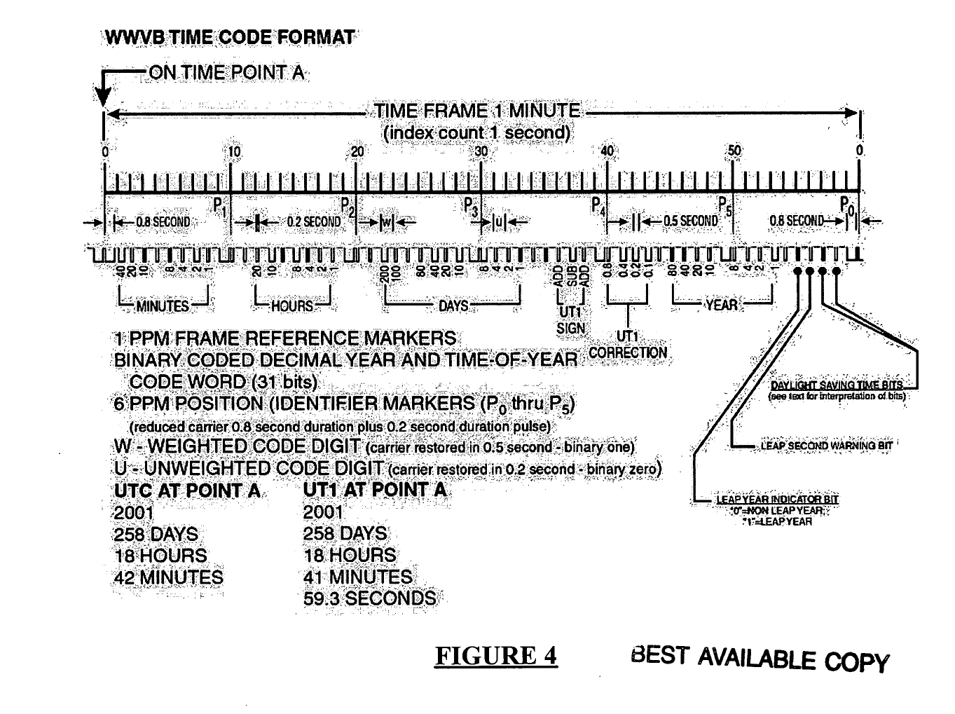

Referring to FIG. 4, depicted is the WWVB time code format. The receiver 104 receives the WWVB time coded signal at 60 kHz and the demodulator/decoder 106 demodulates and decodes this amplitude modulated (AM) digital time code format. The demodulator/decoder 106 demodulates the WWVB time code format and detects the demodulated pulse amplitudes and timing of the pulses.

The invention, therefore, is well adapted to carry out the objects and attain the ends and advantages mentioned, as well as others inherent therein. While the invention has been depicted, described, and is defined by reference to exemplary embodiments of the invention, such a reference does not imply a limitation on the invention, and no such limitation is to be inferred. The invention is capable of considerable modification, alternation, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects.

1. An apparatus for receiving and decoding a radio frequency time signal, comprising:
a time signal receiver for receiving a time signal;
a demodulator-decoder coupled to the time signal receiver, wherein the demodulator-decoder determines time information from the received time signal; and
a time register for storing the time information.

2. The apparatus of claim 1, wherein the time signal receiver is coupled to an antenna for reception of the time signal.

3. The apparatus of claim 1, wherein the time signal receiver, the demodulator-decoder and the time register are fabricated on an integrated circuit die.

4. The apparatus of claim 3, further comprising the integrated circuit die being packaged in an integrated circuit package.

5. The apparatus of claim 4, wherein the integrated circuit package is selected from the group consisting of PDIP, SOIC, MSOP, TSSOP, and QSOP.

6. The apparatus of claim 1, further comprising a digital processor coupled to the demodulator-decoder and time register.

7. The apparatus of claim 4, wherein the digital processor, the time signal receiver, the demodulator-decoder and the time register are fabricated on at least one integrated circuit die.

8. The apparatus of claim 5, further comprising the at least one integrated circuit die being packaged in an integrated circuit package.

9. The apparatus of claim 8, wherein the integrated circuit package is selected from the group consisting of PDIP, SOIC, MSOP, TSSOP, and QSOP.

10. The apparatus of claim 4, wherein the digital processor is selected from the group consisting of a microcontroller, a microprocessor, a programmable logic array (PLA), an application specific integrated circuit (ASIC) and a digital signal processor (DSP).

11. The apparatus of claim 1, wherein the demodulator-decoder comprises:
an envelope detector coupled to an output of the time signal receiver;
an envelope filter coupled to an output of the envelope detector;
a data slicer coupled to an output of the envelope filter;
a data bit decoder coupled to an output of the data slicer;
a receiver buffer register coupled to an output of the data bit decoder; and
a control circuit coupled to the envelope detector, data slicer, data bit decoder and receiver buffer register.

12. The apparatus of claim 10, further comprising a digital processor having a peripheral interface coupled to the receiver buffer register.

13. The apparatus of claim 1, wherein the demodulator-decoder comprises a timer and a digital filter.

14. The apparatus of claim 1, wherein the demodulator-decoder comprises a frequency-to-voltage converter, a first low pass filter, a second low pass filter and a voltage comparator.

15. A timing system using a radio frequency time signal, said system comprising:
a time signal receiver for receiving a time signal;
a demodulator-decoder coupled to the time signal receiver, wherein the demodulator-decoder determines time information from the received time signal;
a time register for storing the time information; and
a digital processor coupled to the demodulator-decoder and time register.

16. The timing system of claim 15, wherein the timing system is selected from the group consisting of clocks, time of use utility meters, traffic lights; bus, train and plane scheduling apparatus; speed measuring instruments used in combination with global positioning satellite (GPS) devices, timers, and parking meters.

17. A method for providing time information from radio time signal, said method comprising the steps of:
receiving a time signal with a time signal receiver;
determining time information from the received time signal with a demodulator-decoder coupled to the time signal receiver; and
storing the time information in a time register.

18. The method of claim 17, further comprising the step of coupling a digital processor to the demodulator-decoder and time register.

19. The method of claim 17, further comprising the step of providing the time information to a timing system.

20. The method of claim 19, wherein the timing system is selected from the group consisting of clocks, time of use utility meters, traffic lights; bus, train and plane scheduling apparatus; speed measuring instruments used in combination with global positioning satellite (GPS) devices, timers, and parking meters.
